(19) United States
(12) Patent Application Publication
(10) Pub. No.: US 2013/0049672 A1
(43) Pub. Date: Feb. 28, 2013

(54) Mobile Telephone Wireless Earpiece Storage and Charging Device

(71) Applicant: Tyrone W. Taylor, Fort Washington, MD (US)

(72) Inventor: Tyrone W. Taylor, Fort Washington, MD (US)

(21) Appl. No.: 13/217,183

(22) Filed: Aug. 24, 2011

(51) Int. Cl. H02J 7/00; H05K 7/00

(52) U.S. Cl. 320/101; 320/107; 24/3.1

(57) ABSTRACT

Systems, methods and apparatus for providing mobile telephone wireless earpiece storage and charging are disclosed. In an aspect of the present invention, an apparatus includes a belt attachment member, a body coupled to the belt attachment member, and a coupling member coupled to the body and capable of removably securing a portable wireless device such as a Bluetooth earpiece.

### BACKGROUND OF THE INVENTION

1. Field of the Invention

The present invention generally relates to communication devices, and more particularly to systems, methods and apparatus for use with wireless communication devices.

2. Related Art

Bluetooth® technology is a short-distance wireless communication technology that achieves low-cost results and that can function with low power capability. Bluetooth is used in many types of mobile or portable communication devices. For example, the Bluetooth technology wireless transmission function is used in various types of earpieces/earphones, portable phones, or other mobile devices.

Various kinds of Bluetooth earpieces are commercially available to consumers, and most are used together with Bluetooth mobile phones to allow hands-free communication for the user. That is, a user can wear a Bluetooth earpiece, and regardless of the time and place, use the wireless transmission function of the Bluetooth technology to receive a telephone call with a hands-free effect.

A Bluetooth earpiece provides wireless communication capability within a short distance such as, for example, approximately 10 meters to 100 meters, without being limited to any transmission direction or interruptions by any obstacle.

Currently, when a user wishes to use a mobile telephone and yet wishes to also have the freedom and mobility of hands-free communication, the user simply places the Bluetooth wireless earpiece over their ear. The Bluetooth earpiece provides increased safety for the user such as, for example, by allowing the user to drive a vehicle without holding the mobile telephone and to perform other tasks safely and with less chance of distraction.

However, the Bluetooth earpiece is a small-sized device that the user can easily misplace, lose, or drop, and this problem adds expenses for the user in terms of the cost of replacing the lost earpiece or the inconvenience for the user in trying to locate a lost earpiece. Currently, users are not commonly provided a holding device for storing a Bluetooth earpiece that is not being used. Additionally, it can be inconvenient for the user to retrieve an earpiece that is held within a pocket (or purse or backpack) of a user. Furthermore, there is also a problem of “ghost dialing” by the Bluetooth earpiece when the earpiece is held in a pocket, purse, or backpack, due to the pressure exerted to the earpiece's button(s) within the pocket, purse, or backpack.

Other problems can potentially occur with Bluetooth earpieces. For example, the power stored in the Bluetooth earpiece does not last all day and requires recharging when the power becomes dissipated. Therefore, the Bluetooth earpiece becomes inoperable for users who are mobile for long periods of time (such as, for example, travelers) because they may not have immediate access to a wall outlet or power sources. As another example, if the user decides to wear the Bluetooth earpiece on their ear, the user's head or ear is subject to excessive radio waves for longer periods of time. Therefore, it would be advantageous to provide users with safer methods of using the portable devices.

In one approach, U.S. Patent Pub. 2006/0237494 discloses a telephone holster for holding a wireless telephone and for attachment to the user's belt. However, this approach requires multiple components and parts that contribute to added manufacturing complexities and costs, and increases the possibility for the user to misplace or break the multiple components. In another approach relating to power technology, U.S. Pat. No. 7,645,932 discloses an improved solar cell for providing device power. However, it does not disclose specific details on how to modify the disclosed solar cell for the communication device technologies.

Given the foregoing, systems, methods, and apparatus for a mobile telephone wireless earpiece storage and charging device are needed.

### BRIEF DESCRIPTION OF THE INVENTION

This summary is provided to introduce a selection of concepts. These concepts are further described below in the Detailed Description. This summary is not intended to identify key features or essential features of the claimed subject matter, nor is this summary intended as an aid in determining the scope of the claimed subject matter.

The present invention meets the above-identified needs by providing systems, methods, and apparatus for a mobile telephone wireless earpiece storage and charging device.

In an aspect of the present invention, an apparatus includes a belt attachment member, a body coupled to the belt attachment member, and a coupling member coupled to the body and capable of removably securing a portable mobile telephone wireless earpiece. The portable device is, for example, a Bluetooth earpiece.

In another aspect, the apparatus also includes a charging circuit for charging the portable Bluetooth device. The charging circuit can also charge a mobile telephone that can be removably coupled to the apparatus.

In yet another aspect, the apparatus includes a solar charging panel and solar cell for charging a power source in the charging circuit.

In yet another aspect, the apparatus includes an AC charging port circuit for electrically coupling the charging circuit to an AC power supply.

Further features and advantages of the present invention, as well as the structure and operation of various aspects of the present invention, are described in detail below with reference to the accompanying drawings.

### BRIEF DESCRIPTION OF THE DRAWINGS

The features and advantages of the present invention will become more apparent from the detailed description set forth below when taken in conjunction with the drawings in which like reference numbers indicate identical or functionally similar elements. Additionally, the left-most digit of a reference number identifies the drawing in which the reference number first appears.

FIG. 1A is a block diagram that shows an exemplary apparatus according to an aspect of the present invention.

FIG. 1B is a block diagram that shows an exemplary apparatus according to another aspect of the present invention.

FIG. 2 is a block diagram that shows an apparatus according to another aspect of the present invention.

FIG. 3 is a block diagram that shows an apparatus according to another aspect of the present invention.

FIG. 4 is a block diagram that shows an apparatus capable of charging various portable devices according to an aspect of the present invention.

FIG. 5 is a circuit diagram of a power charging system for charging various portable devices according to an aspect of the present invention.

### DETAILED DESCRIPTION

The present invention is directed to systems, methods, and apparatus for a mobile telephone wireless earpiece storage and charging device.

In an aspect of the present invention, an apparatus includes a belt attachment member, a body coupled to the belt attachment member, and a coupling member coupled to the body and capable of removably securing a portable wireless device. The portable wireless device is, for example, a Bluetooth earpiece.

In another aspect, the apparatus also includes a charging circuit for charging the portable wireless device. The charging circuit can also charge a mobile telephone that can be removably coupled to the apparatus.

In yet another aspect, the apparatus includes a solar charging panel and solar cell for charging a power source in the charging circuit.

In yet another aspect, the apparatus includes an AC charging port circuit for electrically coupling the charging circuit to an AC power supply.

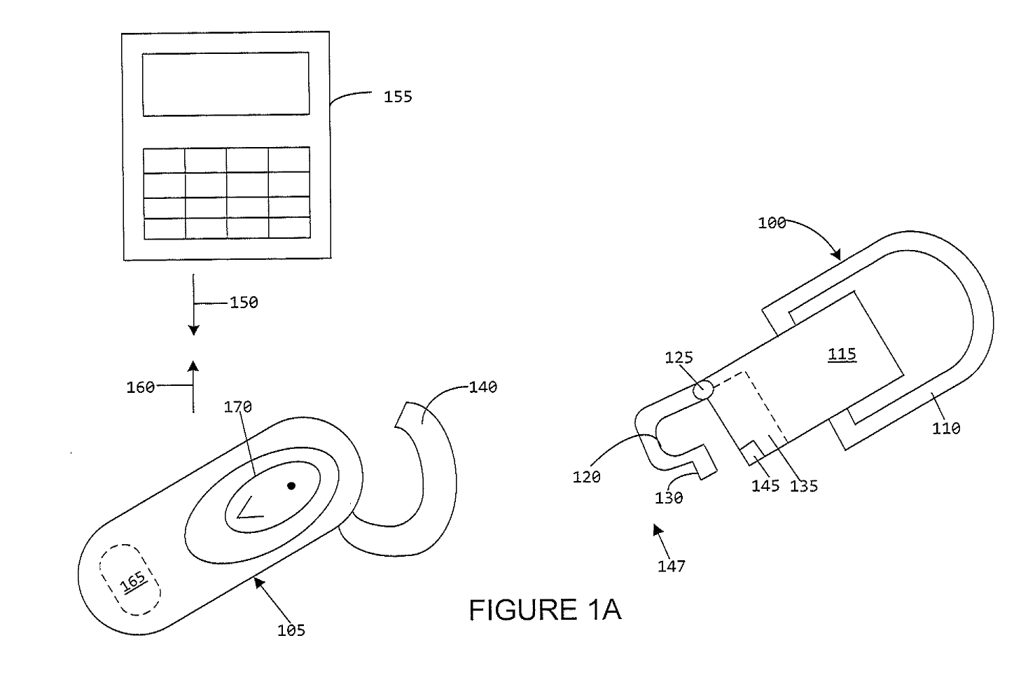

Referring to FIG. 1A, a block diagram illustrating an exemplary apparatus 100, according to an aspect of the present invention, is shown. Apparatus 100 functions as a mobile telephone wireless earpiece storage and charging device that permits the safe storage or the safe holding of a portable Bluetooth device such as, for example, a Bluetooth earpiece 105. In an aspect, apparatus 100 includes a belt loop attachment member 110 (i.e., belt attachment member 110) that can be removably coupled (or removably attached) to a belt (not shown), belt loop, or similar article of clothing. As used herein, two different components that can be removably coupled or removably attached means that the two different components can be attached together and detached apart.

In an aspect, member 110 can be a rigid material, a flexible material, or a semi-rigid material. As an example, member 110 can be rubber, leather, metal, metal alloy, Teflon®, plastic, brass, pewter, a polymer, titanium, another synthetic material, or any other suitable material or any combination of different materials.

Member 110 is coupled to a body 115 or is integral to the body 115. In an aspect, body 115 can be constructed from different materials and can have different shapes in addition to the illustrated shapes in the drawings herein. In an aspect, body 115 is constructed from, for example, plastic, titanium, brass, pewter, a polymer, metal, metal alloy, and/or other suitable materials.

In an aspect, a holding member 120 is coupled to body 115. Holding member 120 pivots along a pivot member 125 that is attached to body 115. Member 120 is a rigid or semi-rigid material such as, for example, rubber or flexible plastic. Holding member 120 is flexible so that a holding member end 130 (of holding member 120) can be inserted into opening 135 in body 115. An ear attachment member 140 (of earpiece 105) is placed on the supporting surface 145 of holding member 120. The ear attachment member 140 is configured to be worn on the ear of the user of earpiece 105. The user then flexes (bends) the holding member 120 in the direction 147 so that the user can insert end 130 into opening 135 with ear attachment member 140 resting on surface 145 of holding member 120. The user then inserts end 130 into opening 135 so that end 130 rests on top of edge 145. As a result, ear attachment member 140 is removably secured by holding member 120 to apparatus 100. Various drawings below illustrate earpiece 105 as secured to apparatus 100. The user can have apparatus 100 attached to their belt, belt loop, or other article of clothing.

Therefore, apparatus 100 provides a convenient device that allows safe and secure holding of earpiece 105. When the user desires to de-engage and remove earpiece 105 from apparatus 100, the user flexes (bends) holding member 120 in direction 147, so that end 130 is disengaged from edge 145 and the user can pull end 130 out of opening 135. As a result, the user can disengage ear attachment member 140 from holding member 120.

Therefore, in an aspect, apparatus 100 provides a device that allows convenient and safe storage of earpiece 105 when it is not in use. The convenient storage function provided by apparatus 100 also minimizes the loss or misplacement of earpiece 105 by a user and saves the user the cost of having to replace a lost earpiece 105. Apparatus 100 eliminates the need for users to continually to ask themselves the common question: “Where did I leave that earpiece?”

Apparatus 100 also eliminates the inconvenience for users in retrieving earpieces stored in their pockets, purses or backpacks, and also decreases the ghost dialing by an earpiece stored in such pockets, purses or backpacks.

Additionally, apparatus 100 provides the following advantageous health benefit. The user is no longer subjected to excessive radio waves on their head or ear for long periods of time when the user wears earpiece 105 on their ear. Rather, the user can removably secure earpiece 105 in other areas of their clothing that can safely receive the radio waves.

Additionally, in an aspect as will be discussed further below, apparatus 100 can provide charging capability to the power source of earpiece 105 when it is connected to apparatus 100. Therefore, this charging capability can conveniently recharge earpiece 105 when its power becomes dissipated and can extend the usage time of earpiece 105. In contrast, conventional technology requires the user to charge a Bluetooth earpiece 105 by plugging the earpiece into a vehicle power charge outlet or into a home or office AC outlet. Therefore, conventional technology does not allow sufficient mobility or flexibility for a mobile user of wireless earpieces 105.

Additionally, in another aspect as will be discussed further below, apparatus 100 can provide charging capability to the power source of another device such as, for example, mobile telephone 155 when it is removably coupled to the apparatus 100. Therefore, this charging capability can conveniently recharge mobile telephone 155 when its power becomes dissipated and can extend its usage time.

As will also be appreciated by those skilled in the relevant art(s), in an aspect, audio information 150 of an incoming call to a Bluetooth-compliant mobile telephone 155 is sent to the Bluetooth earpiece 105 via wireless transmission, and Bluetooth earpiece 105 also sends audio information 160 to mobile telephone 155 via wireless transmissions. Therefore, the Bluetooth communication technology provides two-way audio transmissions that permit the user to engage in hands-free communication via mobile telephone 155. Therefore, a user can engage in telephone calls without having to physically hold mobile telephone 155 up to their ear. The user can also control the functionality of Bluetooth earpiece 105 by use of actuators 170.

When ear attachment member 140 is wrapped around the ear of the user, an earspeaker (not shown) of earpiece 105 is engaged against the ear and directs voice signals 150 into the ear canal of the user. A microphone 165 receives voice signals from the user which are then transmitted by earpiece 105 as audio signals 160 to mobile telephone 155. Mobile telephone 155 then transmits audio signals 160 to a destination device in a telecommunication network. In an aspect, earpiece 105 has no wires and may be configured to interact wirelessly with different Bluetooth-compliant devices such as, for example, handsets, personal digital devices (PDAs), computers, and/or other suitable devices.

Typically, a Bluetooth earpiece includes a Bluetooth module (not shown) and is operative as a wireless technology standard for connecting devices to replace cables. Bluetooth transmissions typically operate in radio frequencies in the 2.5 GHz air interface and can transmit short distances of about 10 meters to 100 meters. Typically, a Bluetooth system has a bandwidth of about one megabyte per second (1 MBPS) with individual packets of up to approximately 2,745 bits. A Bluetooth device may have signal strength of up to, for example, about 100 milliwatts for a range of about 100 meters in certain applications. The Bluetooth protocol is well known to those skilled in the relevant art(s) and further details are readily available in various publications.

As will also be appreciated by those skilled in the relevant art(s), in an aspect, other types of holding members can be used to removably couple earpiece 105 to apparatus 100. For example, in FIG. 1B, holding member 180 can be a clip, snap-on clip, button, Velcro®, magnet, any other locking mechanisms, coupling sleeves pair, and/or Universal Serial Bus (USB) coupling sleeves pair. In an aspect, holding member 180 includes a sleeve member 182 that is securely placed around the ear attachment member 140 of Bluetooth earpiece 105 and a corresponding part 184 that is attached to a body 178 of apparatus 100. In an aspect, body 178 may be a solid body and does not include opening 135. The user can removably attach sleeve member 182 to part 184 and also separate sleeve member 182 from part 184. For example, if sleeve member 182 and part 184 are magnets, snap-on clips or coupling sleeves pair, then holding member 180 provides a suitable locking mechanism that allows apparatus 100 to securely, but removably, hold earpiece 105.

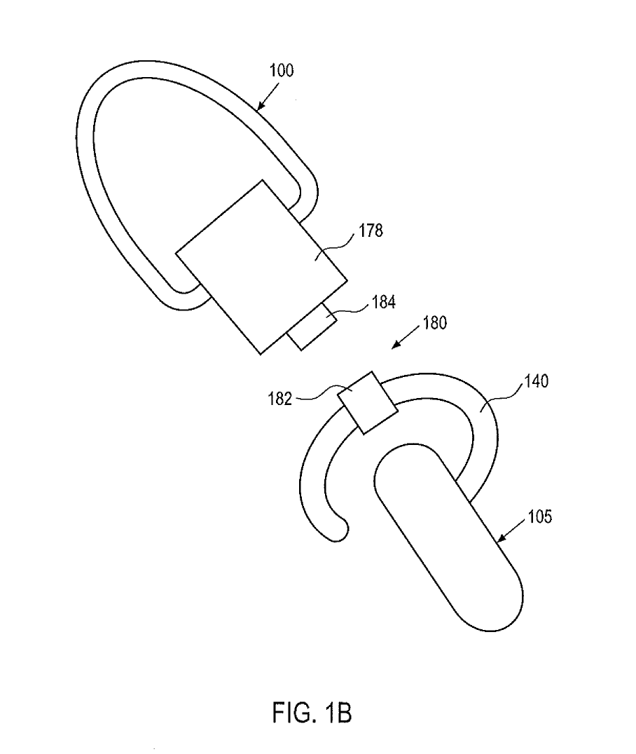

FIG. 2 is a block diagram that shows an apparatus 200 according to another aspect of the present invention. Apparatus 200 includes a belt loop attachment member 210 that can be removably coupled (or removably attached) to a belt (not shown), belt loop, or similar article of clothing. In an aspect, belt loop attachment member 210 is an O-ring. The member 210 can be constructed by at least any of the similar materials as the belt loop attachment member 110 such as, for example, titanium. In an aspect, the belt loop attachment member 210 may be spring loaded in its attachment to the belt or belt loop.

In an aspect, apparatus 200 includes a body 215 which can be constructed by at least any of the similar materials as body 115 such as, for example, plastic. In an aspect, apparatus 200 also includes a coupling member 221 that is inserted into opening 222 of body 215, and is coupled to belt loop attachment member 210. In another aspect, opening 222 is omitted, and coupling member 221 is instead fused or otherwise attached to body 215. In an aspect, coupling member 221 is an O-ring. In yet another aspect, the size of coupling member 221 is less than the size of belt loop attachment member 210. For example, coupling member 221 may be one-third the size of belt loop attachment member 210.

In an aspect, apparatus 200 includes a coupling member 280 that removably couples earpiece 105 (and/or its ear attachment member 140) to body 215 of apparatus 200. In an aspect, coupling member 280 can be similar to coupling members 120 or 180 or any suitable mechanism that removably secures earpiece 105 and/or member 140 to apparatus 200.

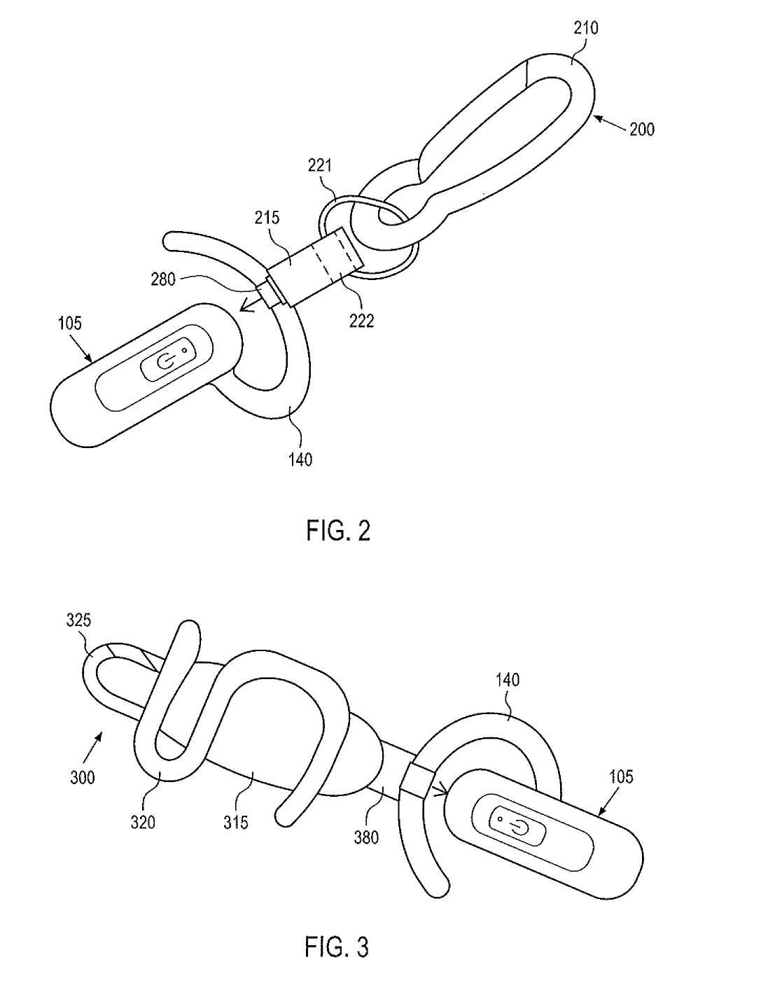

FIG. 3 is a block diagram that shows an apparatus 300 according to another aspect of the present invention. Apparatus 300 includes a body 315 that is similar to body 115, body 178, or body 415. In an aspect, apparatus 300 includes a belt loop attachment member 320 coupled to body 315. Beltloop attachment member 320 is separated from body 315 by a gap through which a belt is inserted. Therefore, when the belt is inserted through this gap, apparatus 300 is removably coupled to the belt. In an aspect, belt loop attachment member 320 is shaped in a format or configuration such as the letter “S” shape as shown in FIG. 3. The shape or configuration of member 320 may vary as will be appreciated by those skilled in the relevant art(s) after reading the description herein.

In an aspect, apparatus 300 includes a belt clip 325 as an optional feature. Belt clip 325 is attached to body 315 or is integral to body 315 and allows apparatus 300 to be removably coupled to a belt, belt loop, or any other article of clothing.

In an aspect, apparatus 300 also includes a coupling member 380 for removably coupling earpiece 105 to body 315. In an aspect, coupling member 380 can be similar to coupling members 120 or 180, or any suitable mechanism that removably secures earpiece 105 and/or member 140 to apparatus 300.

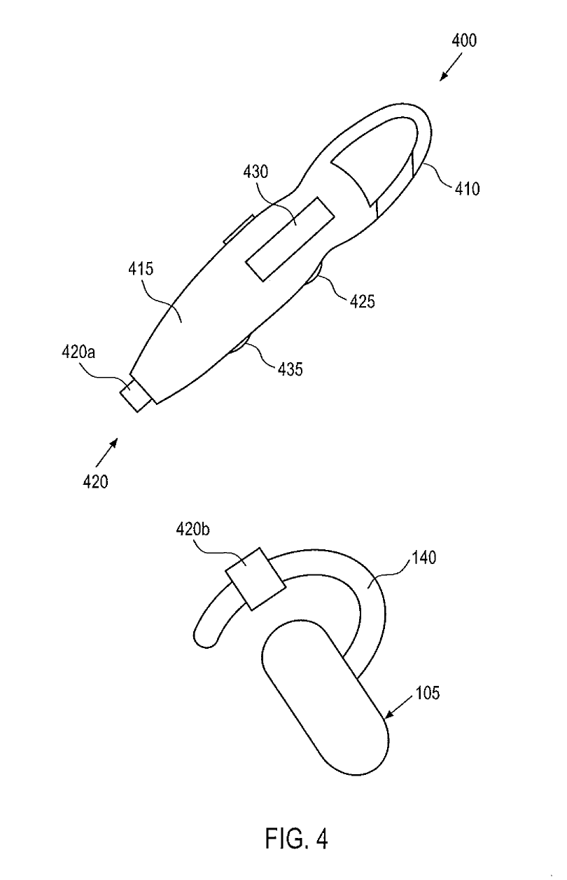

FIG. 4 is a block diagram that shows an apparatus 400 capable of charging various portable devices according to an aspect of the present invention. In an aspect, apparatus 400 includes a belt clip (or a belt attachment member) 410 that is attached to or integral to a body 415. Apparatus 400 also includes a coupling member 420 for removably coupling earpiece 105 to body 415 of apparatus 400. In an aspect, coupling member 420 can be similar to coupling members 120 or 180, or any suitable mechanism that removably secures earpiece 105 and/or member 140 to apparatus 400.

In an aspect, apparatus 400 is configured to fully recharge a portable wireless device 105 such as, for example, a Bluetooth earpiece. As an example, the charge time provided by apparatus 400 to a Bluetooth device will be about one hour or less, which is considered a relatively rapid charge rate. In an aspect, coupling member 420 is a connector that permits apparatus 400 to provide voltage signals to earpiece 105 so that apparatus 400 can recharge the power supply of earpiece 105. As an example, coupling member 420 includes a USB connector part 420a attached to body 415 and USB connector part 420b that is attached to earpiece 105, where coupling member 420 can transmit a voltage output from apparatus 400 to earpiece 105 in order to allow the power charging of the power supply of earpiece 105. When the user removably couples part 420b to part 420a, apparatus 400 securely holds earpiece 105 and is also electrically coupled to the power supply of earpiece 105 for purposes of charging earpiece 105.

In an aspect, apparatus 400 can optionally include an AC charging port 425 that electrically connects to an AC power source such as, for example, an AC power source from a wall outlet or from an automobile power outlet. Port 425 permits the user to charge the power supply of apparatus 400 from the AC power source. Additionally or alternatively, apparatus 400 may optionally include a solar charging panel 430. Panel 430 receives light as solar energy for charging the power supply of apparatus 400. This power supply from apparatus 400 can charge a Bluetooth earpiece 105 and/or a mobile telephone 155. Additionally or alternatively, apparatus 400 may optionally include a mobile telephone connection port 435. Port 435 permits the user to charge the power supply of a mobile telephone 155 that can be removably coupled to port 435.

In other aspects of the present invention, apparatus 400 includes the coupling member 420, but any or all of ports 425 and 435, and/or solar panel 430 may be omitted.

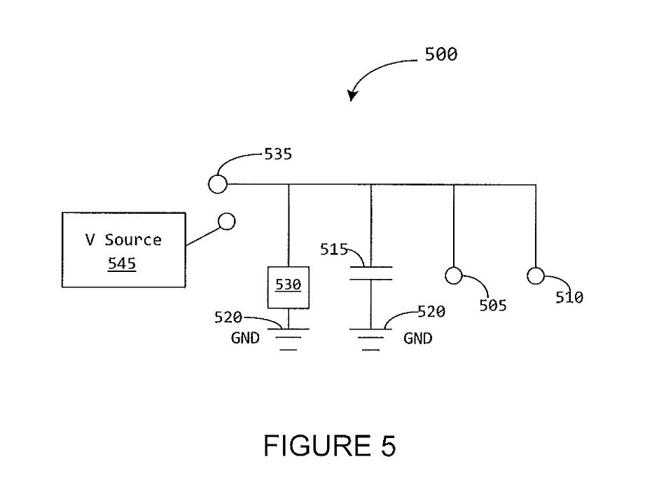

FIG. 5 is a circuit diagram of a power charging system (circuit) 500 for charging various portable devices according to an aspect of the present invention. In an aspect, circuit 500 includes a power source 515. Power source 515 can be, for example, a Lithium Ion battery or any suitable rechargeable battery source or other suitable power source. Power source 515 provides voltage output through terminal 505 when earpiece 105 is removably electrically coupled to coupling member 420. Therefore, power source 515 provides charging power to charge the power supply of earpiece 105. Power source 515 provides voltage output through terminal 510 when mobile telephone 155 is removably electrically coupled to port 435. Therefore, power source 515 provides charging power to charge the power supply of mobile telephone 155 in an aspect of apparatus 400 that includes port 435.

In an aspect of apparatus 400 that includes solar panel 430, circuit 500 includes solar cell 530 that converts the light received by solar panel 430 into voltage signals. These voltage signals from solar cell 530 can charge the voltage level of power source 515, which in turn can charge earpiece 105 and/or mobile telephone 155.

In an aspect of apparatus 400 that includes AC charging port 435, circuit 500 includes input voltage terminal 535 that is electrically coupled to charging port 435. When the user electrically connects the port 435 to a power source such as, for example, a voltage source 545 which can be an AC power source, the voltage from voltage source 545 can charge the voltage level of power source 515. Various known circuit elements such as, for example, rectifiers and circuit traces, can be included in circuit 500 and are not shown in FIG. 5 so as to not overcrowd the drawings. As mentioned above, the voltage from the power source 515 can charge the earpiece 105 and/or the mobile telephone 155.

These components as illustrated and described could be formed on a circuit board or other support and mounted within the apparatus 400. Some of the components as described can be formed as an integrated circuit and contained within the apparatus 400. The components can be mounted on a dielectric substrate (e.g., a circuit board) or other suitable submounts known to those skilled in the relevant art(s). A circuit board, substrate, or submount could refer to any dielectric substrate, PCB, ceramic substrate or other circuit carrying structures for carrying or transmitting signals in electronic components.

In another aspect, the invention is implemented primarily in hardware using, for example, hardware components such as application specific integrated circuits (ASICs). Implementation of the hardware state machine so as to perform the functions described herein will be apparent to persons skilled in the relevant art(s).

In yet another aspect, the invention may be implemented using a combination of both hardware and software.

While various aspects of the present invention have been described above, it should be understood that they have been presented by way of example and not limitation. It will be apparent to persons skilled in the relevant art(s) that various changes in form and detail can be made therein without departing from the spirit and scope of the present invention. Thus, the present invention should not be limited by any of the above described exemplary aspects, but should be defined only in accordance with the following claims and their equivalents.

In addition, it should be understood that the figures in the attachments, which highlight the structure, methodology, functionality and advantages of the present invention, are presented for example purposes only. The present invention is sufficiently flexible and configurable, such that it may be implemented in ways other than that shown in the accompanying figures.

Further, the purpose of the foregoing Abstract is to enable the U.S. Patent and Trademark Office and the public generally and especially the scientists, engineers and practitioners in the relevant art(s) who are not familiar with patent or legal terms or phraseology, to determine quickly from a cursory inspection the nature and essence of this technical disclosure. The Abstract is not intended to be limiting as to the scope of the present invention in any way.

What is claimed is:

1. An apparatus comprising:
a body;
a belt attachment member coupled to the body; and
a coupling member coupled to the body and capable of removably securing a portable wireless device.

2. The apparatus of claim 1, wherein the portable wireless device comprises a Bluetooth earpiece.

3. The apparatus of claim 1, further comprising a charging circuit capable of charging the portable Bluetooth device.

4. The apparatus of claim 4, wherein the charging circuit is further configured to charge a mobile telephone.

5. The apparatus of claim 1, further comprising an AC charging port capable of electrically coupling the apparatus to an AC power source.

6. The apparatus of claim 5, wherein the AC power source is capable of charging a power source in the apparatus.

7. The apparatus of claim 1, further comprising a mobile telephone connection port capable of electrically coupling a mobile telephone to the apparatus.

8. The apparatus of claim 1, further comprising:
a solar panel capable of receiving light; and
a solar cell coupled to the solar panel and capable of providing a voltage output converted from the light.

9. The apparatus of claim 8, wherein the solar cell provides the voltage output to charge a voltage source in the apparatus.

10. The apparatus of claim 9, wherein the voltage source is capable of charging the portable Bluetooth device.

11. The apparatus of claim 9, wherein the voltage source is capable of charging a mobile telephone that is removably coupled to the apparatus.

12. An apparatus comprising:
a body;
means for removably coupling the body to article of clothing; and
means for removably coupling a portable wireless device to the body.

13. The apparatus of claim 12, wherein the portable wireless device comprises a Bluetooth earpiece.

14. The apparatus of claim 12, further comprising means for charging the portable Bluetooth device.

15. The apparatus of claim 14, further comprising means for charging a mobile telephone.

16. The apparatus of claim 12, further comprising means for electrically charging the apparatus from an AC power source.

17. The apparatus of claim 12, further comprising means for electrically charging the apparatus from a received light.
